(19) United States
(12) Patent Application Publication
(10) Pub. No.: US 2019/0170918 A1
(43) Pub. Date: Jun. 6, 2019

(54) Irregular Shaped Display Panel, Method and Device for Manufacturing Irregular Shaped Display Panel, and Display Device

(71) Applicants: BOE TECHNOLOGY GROUP CO., LTD., Beijing (CN); ORDOS YUANSHENG OPTOELECTRONICS CO., LTD., Ordos (CN)

(72) Inventors: Yun QIAO, Beijing (CN); Zhengkui WANG, Beijing (CN); Lele CONG, Beijing (CN); Han ZHANG, Beijing (CN); Zhen WANG, Beijing (CN); Wenwen QIN, Beijing (CN); Jianjun ZHANG, Beijing (CN); Wei LI, Beijing (CN); Xuelu WANG, Beijing (CN); Yanqing CHEN, Beijing (CN); Jianyun XIE, Beijing (CN); Cheng LI, Beijing (CN); Jian SUN, Beijing (CN)

(21) Appl. No.: 16/142,326

(22) Filed: Sep. 26, 2018

(30) Foreign Application Priority Data
Dec. 5, 2017 (CN) 201711269743.9

(51) Int. Cl. G02B 5/20; G03F 7/00

(52) U.S. Cl. CPC G02B 5/201; G03F 7/0007

(57) ABSTRACT

An irregular shaped display panel, a method and a device for manufacturing the irregular shaped display panel, and a display device are provided. The irregular shaped display panel includes a display area and a non-display area surrounding the display area. The method for manufacturing an irregular shaped display panel includes: determining, based on an irregular shaped region on the display panel, boundary pixel units located on a boundary of the irregular shaped region; dividing each boundary pixel unit into at least two pixel division units such that each pixel division unit comprises parts of all sub-pixels of the boundary pixel unit; and determining whether a ratio of an area of each pixel division unit outside the display area to an area of the entire pixel division unit reaches a preset value; if yes, performing a shading process on the pixel division unit.

### CROSS-REFERENCE TO RELATED APPLICATION

This application claims the benefit of priority to Chinese Patent Application No. 201711269743.9 filed on Dec. 5, 2017, the contents of which are incorporated herein in their entirety by reference.

### TECHNICAL FIELD

The present disclosure relates to the field of display technology, and particularly relates to an irregular shaped display panel, a method and a device for manufacturing the irregular shaped display panel, and a display device.

### BACKGROUND

With the continuous development of display technology, various types of display screens have emerged, such as liquid crystal display screens, and organic light-emitting display screens, which have gradually become the mainstream products of the current display industry. Further, with the popularity of display screens in smart wearable devices and other portable electronic devices (such as watches, wearable phones, etc.), irregular shaped display screens are increasingly favored by consumers, broaden application field of the display screens, and further meet people's requirements for display. Therefore, the irregular shaped display screens have become one of the research hotspots in the display field.

### SUMMARY

In one aspect, the present disclosure provides a method for manufacturing an irregular shaped display panel, the irregular shaped display panel including a display area and a non-display area surrounding the display area, the method including:

determining, based on an irregular shaped region on the display panel, boundary pixel units located on a boundary of the irregular shaped region;

dividing each boundary pixel unit into at least two pixel division units such that each of the at least two pixel division units includes parts of all sub-pixels of the boundary pixel unit; and

determining whether a ratio of an area of each pixel division unit outside the display area to an area of the entire pixel division unit reaches a preset value; if it is determined that the ratio reaches the preset value, performing a shading process on the pixel division unit.

Optionally, each boundary pixel unit includes a red sub-pixel, a green sub-pixel, and a blue sub-pixel, and each pixel division unit of the boundary pixel unit includes parts of the red sub-pixel, the green sub-pixel, and the blue sub-pixel.

Optionally, when the ratio of the area of each pixel division unit outside the display area to the area of the entire pixel division unit is equal to or greater than 50%, the shading process is performed on the pixel division unit.

Optionally, the step of performing a shading process on the pixel division unit includes:

covering the pixel division unit with a black opaque material.

Optionally, each boundary pixel unit is equally divided into two pixel division units or four pixel division units.

Optionally, the step of determining whether a ratio of an area of each pixel division unit outside the display area to an area of the entire pixel division unit reaches a preset value includes: identifying positions and the number of the at least two pixel division units of each boundary pixel unit; determining whether each pixel division unit is completely located in the display area, partially located in the display area, or not located in the display area at all, and determining, only for every pixel division unit that is partially located in the display area, whether the ratio of the area of the pixel division unit outside the display area to the area of the entire pixel division unit reaches the preset value.

In another aspect, the present disclosure further provides a device for manufacturing an irregular shaped display panel, the irregular shaped display panel including a display area and a non-display area surrounding the display area, and the device including:

a processing module, configured to determine, based on an irregular shaped region on the display panel, boundary pixel units on a boundary of the irregular shaped region;

a division module, configured to divide each boundary pixel unit into at least two pixel division units such that each pixel division unit includes parts of all sub-pixels of the boundary pixel unit;

an identification and determination module, configured to determine whether a ratio of an area of each pixel division unit outside the display area to an area of the entire pixel division unit reaches a preset value; and

an execution module, configured to perform a shading process on the pixel division unit when the identification and determination module determines that the ratio of the area of the pixel division unit outside the display area to the area of the entire pixel division unit reaches the preset value.

Optionally, each boundary pixel unit includes a red sub-pixel, a green sub-pixel, and a blue sub-pixel, and each pixel division unit of the boundary pixel unit includes parts of the red sub-pixel, the green sub-pixel, and the blue sub-pixel.

Optionally, when the identification and determination module determines that the ratio of the area of the pixel division unit outside the display area to the area of the entire pixel division unit is equal to or greater than 50%, the execution module performs the shading process on the pixel division unit.

Optionally, a material used by the execution module to perform the shading process on the pixel division unit is a black opaque material.

Optionally, the division module is configured to equally divide each boundary pixel unit into two pixel division units or four pixel division units.

Optionally, the identification and determination module is configured to identify positions and quantity of the at least two pixel division units of each boundary pixel unit; determine whether each pixel division unit is completely located in the display area, partially located in the display area, or not located in the display area at all, and determine, only for every pixel division unit that is partially located in the display area, whether the ratio of the area of the pixel division unit outside the display area to an area of the entire pixel division unit reaches the preset value.

In another aspect, the present disclosure also provides an irregular shaped display panel manufactured by using the above-described method.

Optionally, the irregular shaped display panel provided by the present disclosure may include boundary pixel units on a boundary of an irregular shaped region, each boundary pixel unit being divided into at least two pixel division units, and in each boundary pixel unit, the pixel division unit is covered by a shading unit if a ratio of an area of the pixel division unit outside the display area to an area of the entire pixel division unit reaches a preset value is covered by a shading unit.

Optionally, in each boundary pixel unit, the pixel division unit is covered by the shading unit when the ratio of the area of the pixel division unit outside the display area to the area of the entire pixel division unit is greater than or equal to 50%.

Optionally, the shading unit is made of a black opaque material.

Optionally, each boundary pixel unit includes a red sub-pixel, a green sub-pixel, and a blue sub-pixel, and each pixel division unit of the boundary pixel unit includes parts of the red sub-pixel, the green sub-pixel, and the blue sub-pixel.

Optionally, each boundary pixel unit is equally divided into two pixel division units or four pixel division units.

In another aspect, the present disclosure provides a display device including the irregular shaped display panel of any one of the above solutions.

The additional aspects and advantages of the present disclosure will be set forth in part in the following description, and will become apparent from the following description or be understood through implementations of the present disclosure.

### BRIEF DESCRIPTION OF THE DRAWINGS

The above and/or additional aspects and advantages of the present disclosure will become apparent and readily understood from the following description of embodiments in conjunction with the accompanying drawings, in which:

FIG. 1 is a schematic diagram illustrating display of an irregular shaped display panel, in which each boundary pixel unit is equally divided into two pixel division units, according to an embodiment of the present disclosure;

FIG. 2 is a schematic diagram illustrating display of an irregular shaped display panel, in which each boundary pixel unit is equally divided into four pixel division units, according to an embodiment of the present disclosure;

FIG. 3 is a schematic diagram of a boundary pixel unit, which is equally divided into two pixel division units, of an irregular shaped display panel according to an embodiment of the present disclosure;

FIG. 4 is a schematic diagram of a boundary pixel unit, which is equally divided into four pixel division units, of an irregular shaped display panel according to an embodiment of the present disclosure;

FIG. 5 is a flowchart of a method for manufacturing an irregular shaped display panel according to an embodiment of the present disclosure;

FIG. 6 is a flowchart of sub-steps included in step S300 of FIG. 5; and

FIG. 7 is a schematic block diagram of a device for manufacturing an irregular shaped display panel according to an embodiment of the present disclosure.

### DETAILED DESCRIPTION

The embodiments of the present disclosure are described in detail below, and examples of the embodiments are illustrated in the drawings, wherein the same or similar reference numerals are used to refer to the same or similar elements or elements having the same or similar functions throughout. The embodiments described below with reference to the drawings are intended to be illustrative for explaining the present disclosure only, and are not to be construed as limitations of the present disclosure.

As understood by those of ordinary skill in the art, the singular forms “a”, “an” and “the” are intended to include the plural forms as well, unless specifically indicated otherwise. It will be further understood that the terms “comprises”, “includes”, “comprising “and/or “including,” when used in this specification, indicate the presence of stated features, integers, steps, operations, elements, and/or components, but do not preclude the presence or addition of one or more other features, integers, steps, operations, elements, components, and/or groups thereof. It would be understood that when an element is referred to as being “connected” or “coupled” to another element, it may be directly connected or coupled to another element, or intervening elements may also be present. Further, “connected” or “coupled” as used herein may include a wireless connection or a wireless coupling. As used herein, the term “and/or” includes any and all combinations of one or more of the associated listed items.

As understood by those of ordinary skill in the art, unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

An irregular shaped display screen differs from a conventional display screen mainly in that its display area has a special shape which is non-rectangular. In general, pixel units in a display screen mostly have rectangular structures or other relatively regular structures, and therefore, when being applied to an irregular shaped display screen, the pixel units cannot completely match with a boundary of the display screen at an edge area of the display screen. As a result, the edge area of the display screen may have a sawtooth effect during display, and color deviation is likely to occur, which affect display effect at the edge area.

In order to alleviate or avoid problems of obvious sawtooth effect and a defective color strip at an irregular shaped display boundary of an irregular shaped display device during display, the present disclosure provides an irregular shaped display panel, a method and a device for manufacturing the irregular shaped display panel, and a display device.

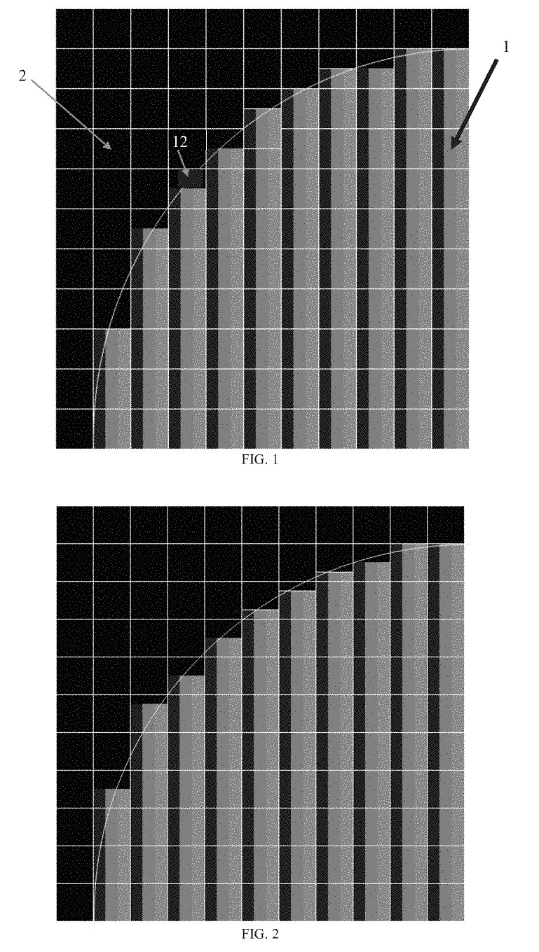

Embodiments of the present disclosure provide an irregular shaped display panel. As shown in FIGS. 1 and 2, the irregular shaped display panel includes a display area 1 and a non-display area 2 around the display area 1 (only parts of the display area and the non-display area of the irregular shaped display panel are shown in FIGS. 1 and 2). Each boundary pixel unit 10 on a boundary of an irregular shaped region is divided into at least two pixel division units 11. In each boundary pixel unit 10, if a ratio of an area of a pixel division unit outside the display area to a total area of the pixel division unit reaches a preset value, the pixel division unit is provided thereon with the shading unit 12. In other words, in each boundary pixel unit 10, each pixel division unit whose ratio of an area outside the display area to a total area reaches a preset value is provided thereon with the shading unit 12. It should be noted that only one shading unit is shown in FIG. 1 in order not to affect illustration of the boundary of the irregular shaped display panel. The more the pixel division units 11 formed by dividing each boundary pixel unit 10, the smaller the height difference between the boundary pixel unit 10 and its adjacent boundary pixel unit 10, so that the display at the irregular shaped region is smoother and the sawtooth effect is less obvious. It could be understood that the boundary of the irregular shaped region usually has a circular shape, an elliptical shape or an oblique shape, and may also have other irregular shape.

In an embodiment, the preset value may be 50%, that is, if a ratio of an area of a pixel division unit 11 outside the display area to a total area of the pixel division unit 11 reaches or exceeds 50%, the pixel division unit 11 is provided thereon with the shading unit 12. The shading unit 12 may be disposed to completely cover the pixel division unit 11 to perform a shading processing on the pixel division unit, so that the entire pixel division unit 11 is in a non-display state. If a ratio of an area of a pixel division unit 11 outside the display area to an area of the entire pixel division unit is smaller than 50%, the pixel division unit 11 can perform display normally.

In an embodiment, each boundary pixel unit 10 includes a red (R) sub-pixel, a green (G) sub-pixel, and a blue (B) sub-pixel, and each pixel division unit 11 formed by dividing the boundary pixel unit includes parts of the R sub-pixel, the G sub-pixel and the B sub-pixel, and thus the pixel division unit 11 can fully perform color display. In order that display effect of the pixel division unit 11 is more realistic, the areas respectively occupied by the R sub-pixel, the G sub-pixel, and the B sub-pixel in each pixel division unit 11 are equal, so that better display can be realized.

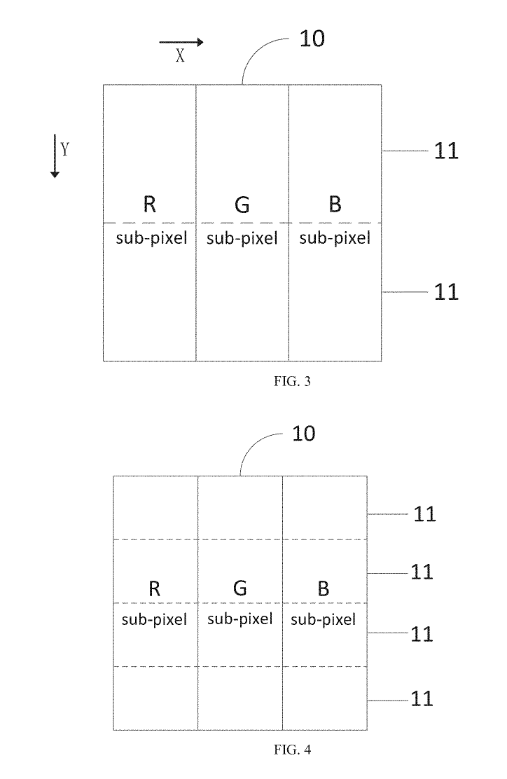

How to divide a boundary pixel unit 10 into pixel division units 11 is based on the arrangement of the R sub-pixel, the G sub-pixel, and the B sub-pixel in the boundary pixel unit 10, which is not limited in the present disclosure, as long as every pixel division unit 11 formed by the division includes parts of the R sub-pixel, the G sub-pixel and the B sub-pixel. In an embodiment, each of the pixel units (including pixel units in the display area for normal display and the boundary pixel units 10) is provided therein with three sub-pixels, namely, R sub-pixel, G sub-pixel, and B sub-pixel. The R sub-pixel, the G sub-pixel, and the B sub-pixel each extend in a Y direction (i.e., the length direction of each of the three sub-pixels is the Y direction), and are sequentially arranged in an X direction perpendicular to the Y direction (for example, as shown in FIGS. 3 and 4). If the pixel unit can be regarded to have a square structure, the pixel unit having the square structure may be divided along a cross-sectional direction substantially parallel to the X direction, so that each pixel division unit 11 formed by the division includes parts of the R sub-pixel, the G sub-pixel and the B sub-pixel. It should be noted that the boundary pixel units 10 and common pixel units (i.e., other pixel units than the boundary pixel units 10) have a same structure, but are located at different positions. The division in the present disclosure is not a physical division, but means that by dividing each boundary pixel unit into a plurality of pixel division units 11, a single pixel division unit 11 is taken as one calculation unit to perform calculation, so as to determine whether the pixel division unit 11 should be covered, thereby determining a shading area of each boundary pixel unit 10. Emission of each pixel division unit 11 is not controlled separately, that is, all of the pixel division units 11 in a single boundary pixel unit 10 are in a same illumination state (i.e., all in a light-emitting state or all in a non-light-emitting state). However, light emitted from each pixel division unit 11 that is provided thereon with the shading unit 12 cannot be normally emitted out due to the shading of the shading unit 12, and thus the pixel division unit 11 presents a non-display state. Further, in the present disclosure, the boundary pixel unit 10 may be divided equally or not equally. In other words, the plurality of pixel division units 11 formed by dividing the boundary pixel unit 10 may have a same area or have different areas. In an embodiment, a plurality of pixel division units 11 having a same area are formed by equally dividing the boundary pixel unit 10, as such, display height difference between two adjacent boundary pixel units 10 is more uniform, thereby ensuring a smaller height difference. In the following description and embodiments of the present disclosure, a case where the boundary pixel unit 10 is divided equally into two or more pixel division units 11 having a same area will be described as an example.

As shown in FIG. 3, in the present disclosure, the three sub-pixels of the boundary pixel unit are arranged along the X direction (lateral direction).

Referring to FIG. 3, in a case where the boundary pixel unit 10 is divided into two pixel division units 11, the boundary pixel unit 10 is divided along a cross-section of the three sub-pixels parallel to the X direction such that each pixel division unit 11 includes parts of the R sub-pixel, the G sub-pixel, and the B sub-pixel, and the R sub-pixel, the G sub-pixel, and the B sub-pixel of each pixel division unit 11 have a same area. In the present disclosure, in order to ensure that the boundary pixel unit 10 at the irregular shaped region presents smaller sawtooth during display, the boundary pixel unit 10 may be equally divided. For example, in a case where the boundary pixel unit 10 is equally divided into two pixel division units 11, the boundary pixel unit 10 is divided along a cross-section passing through a midpoint of the square structure thereof in the Y direction and parallel to the X direction, and if the boundary pixel unit 10 is divided into three pixel division units 11, four pixel division units 11 or more pixel division units 11, the boundary pixel unit 10 is divided equally along a corresponding cross-section. In some embodiments, the boundary pixel unit 10 is divided into two or four pixel division units 11 for ease of implementation. Referring to FIGS. 3 and 4, FIG. 3 shows a structure of a boundary pixel unit 10 which is equally divided into two pixel division units 11, and FIG. 4 shows a structure of a boundary pixel unit 10 which is equally divided into four pixel division units 11. In the present disclosure, the more the pixel division units 11 formed by dividing a single boundary pixel unit 10, the more accurate the pixel display, and the smaller the height difference between adjacent pixel division units 11 at the irregular shaped region (e.g., region having a circular shape, an oblique shape, etc.) during display, which results in better smoothness and smaller sawteeth during display, and thus the displayed image is closer to the irregular shaped region in shape.

The pixel division unit 11 formed by the division has two display states, i.e., a display state and a non-display state. It should be noted that the plurality of pixel division units 11 formed by dividing a single boundary pixel unit 10 are in a same illumination state, but may be in different display states. For example, in a case where one boundary pixel unit 10 that is divided to form a plurality of pixel division units 11 is in a light-emitting state, the plurality of pixel division units 11 in the boundary pixel unit 10 are all in a light-emitting state, but the pixel division unit 11 provided with the shading unit 12 is in a non-display state as being shaded by the shading unit 12, and the pixel division unit 11 that is not provided with the shading unit 12 may be in a display state. The shading unit 12 may be made of a black opaque material and cover the pixel division unit 11, so as to shade the pixel division unit 11. In order to avoid light leakage among sub-pixels and enhance color contrast, the display panel is provided with a black matrix. In an embodiment, the shading unit 12 is formed simultaneously with the black matrix of the display panel using a same material. That is, the shading unit 12 is formed on the pixel division unit 11 that is determined to be shaded while forming the black matrix.

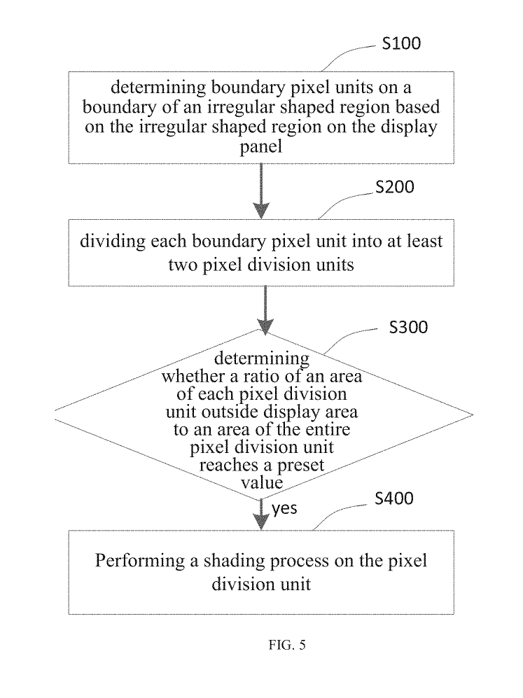

The embodiments of the present disclosure further provide a method for manufacturing an irregular shaped display panel. As shown in FIG. 5, the method may include steps S100 to S400.

In step S100, boundary pixel units on a boundary of an irregular shaped region are determined based on the irregular shaped region on the display panel.

It should be noted that the irregular shaped region may be arc-shaped, circle-shaped or slope-shaped, and is generally located at a boundary position of the entire display panel. In order to make display at the boundary of the entire display panel smoother, it is necessary to first distinguish the boundary pixel units in the irregular shaped region from other pixel units that perform display normally for the subsequent operation. A method for determining the boundary pixel units may include acquiring position information by scanning using software so as to determine the boundary pixel units. However, the present disclosure is not limited to this method, and may also adopt other method, as long as the boundary pixel units on the boundary of the irregular shaped region can be determined.

In step S200, every boundary pixel unit is divided into at least two pixel division units such that each pixel division unit includes parts of all sub-pixels included in the boundary pixel unit.

In order that each pixel division unit includes parts of all sub-pixels included in the boundary pixel unit, the boundary pixel unit may be divided into at least two pixel division units along a cross-section of the boundary pixel unit. The cross-section of the boundary pixel unit may be determined in various ways. For example, the cross-section may be determined by inputting parameters of the display penal itself and obtaining arrangement of the R sub-pixel, the G sub-pixel, and the B sub-pixel in the pixel unit of the display panel. Alternatively, relevant parameter information of the display panel may be automatically obtained through system scanning to determine the cross-section. Also, the cross-section may be determined by other known methods, which is not limited in the present disclosure.

The more the pixel division units formed by division, the smoother the display at the boundary position of the display panel. As described above, the boundary pixel unit may be equally divided, and the pixel division units formed by the division have a same area. For example, as shown in FIG. 3, each boundary pixel unit on the boundary of the irregular shaped region of the display panel is equally divided into two pixel division units, or as shown in FIG. 4, each boundary pixel unit on the boundary of the irregular shaped region of the display panel is equally divided into four pixel division units.

In step S300, it is determined whether a ratio of the area outside the display area to the total area in each pixel division unit is larger than or equal to a preset value, so as to determine whether the pixel division unit is to be subjected to the shading processing.

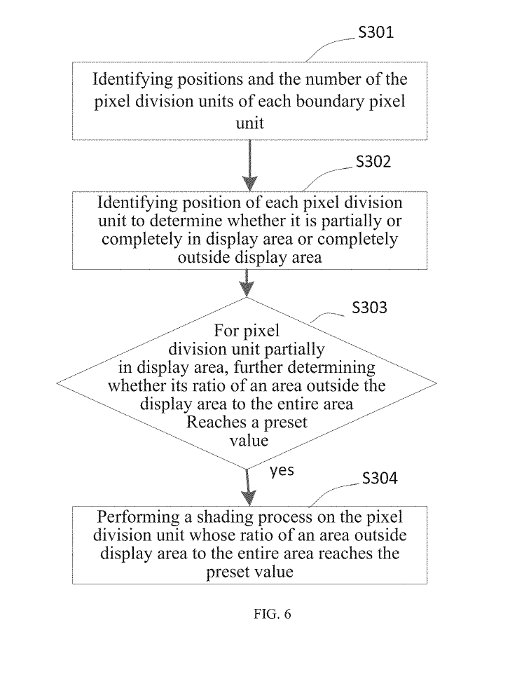

Referring to FIG. 6, step S300 may include the following steps S301 to S303.

In step S301, positions and the number of the pixel division units of the boundary pixel unit are obtained. Optionally, the positions and the number of the pixel division units of the boundary pixel unit may be obtained using various methods, for example, parameters of the pixel division units may be obtained through progressive scan, or parameters may be directly set by the system for retrieve.

In step S302, the position of each pixel division unit is determined, that is, whether each pixel division unit is completely located in the display area, partially located in the display area, or not located in the display area at all (i.e., completely located in the non-display area) is determined. The positions of the pixel division units are determined for subsequent determination.

In step S303, for each pixel division unit that is partially located in the display area, it is further determined whether a ratio of the area of the pixel division unit outside the display area to the total area of the pixel division unit is equal to or larger than a preset value. The pixel division unit(s) completely located in the display area or completely in the non-display area is automatically filtered and will not be subjected to the process of this step, and only when the pixel division unit is determined to be partially located in the display area, whether a ratio of the area of the pixel division unit outside the display area to the total area of the pixel division unit is equal to or larger than a preset value is further determined.

However, the determining method in this step is not limited to determining whether a ratio of the area of the pixel division unit outside the display area to the total area of the pixel division unit reaches a preset value, and may include: determining whether a ratio of an area of the pixel division unit inside the display area to the total area of the pixel division unit reaches a preset value. The two methods result in a same display effect when the preset value is 50%, but when the preset value is not 50%, the display effects will be different. Needless to say, the determination in this step in the present disclosure may be achieved by other method, and the method is included in the protection scope of the present application, as long as its purpose is to compare the ratio of the area of the pixel division unit in the display area to the total area of the pixel division unit with the preset value.

In this step, the preset value may be a preset value in a device, or may be set as practically required. In an embodiment, the preset value is set to be 50%. In this case, if the area of the pixel division unit outside the display area is greater than or equal to 50% of the total area of the pixel division unit, the pixel division unit needs to undergo the shading process, that is, the pixel division unit is a pixel division unit to be shaded. However, the preset value is not limited to 50%, but may also be 20%, 80%, etc. Since 50% is right in the middle, the display is relatively uniform, and display height difference between two adjacent pixel division units is relatively small, making the display smooth.

In step S400, the shading processing is performed on the pixel division unit to be shaded (i.e., the pixel division unit whose ratio of the area outside the display area to the total area reaches the preset value). For the pixel division unit whose ratio of the area outside the display area to the total area does not reach the preset value, this step is not performed.

It should be noted that the shading process herein refers to blocking a pixel division unit using a black opaque material such that the pixel division unit is permanently and physically blocked and no longer display. In an embodiment, the black opaque material may be a material for forming the black matrix, and the black opaque material is formed while forming the black matrix, thereby shading the pixel division unit determined in step S300. In an embodiment, after determining all the pixel division units whose ratios of the areas outside the display area to the total area reach the preset value, a corresponding mask is designed and used, so that the shading units are respectively formed on the pixel division units whose ratios of the areas outside the display area to the total areas reach the preset value while forming the black matrix using the mask. In other words, the black matrix in the present disclosure includes not only a conventional black matrix structure but also the shading units formed on the pixel division units whose ratios of the areas outside the display area to the total areas reach the preset value (i.e., the shading units are formed as a part of the black matrix).

In step S100, determining the boundary pixel units is mainly to determine the positions and the number of the boundary pixel units for further control. When a boundary pixel unit is determined, the boundary pixel unit is divided, for example, along a cross-sectional direction substantially parallel to a direction in which the R sub-pixel, the G sub-pixel and the B sub-pixel are arranged. In an embodiment, the boundary pixel unit may be equally divided into two pixel division units or four pixel division units.

In an embodiment, each boundary pixel unit has the same structure as the pixel unit that performs normal display, and includes three sub-pixel units, that is, R sub-pixel, B sub-pixel, and G sub-pixel, and the three sub-pixels are sequentially arranged in the X direction (lateral direction). During division, each boundary pixel unit 10 is divided into at least two pixel division units along a cross-sectional direction substantially parallel to the X direction, so that each pixel division unit has parts of R sub-pixel, B sub-pixel, and G sub-pixel, and in this way, each pixel division unit can perform a complete display. Since adjacent or adjoining boundary pixel units may have a height difference in the irregular shaped display region, if display of the current boundary pixel units is not well controlled, the display interface may present a sawtooth effect at the boundary display area, thereby affecting display fluency and aesthetics of the entire display area. To reduce or eliminate the sawtooth phenomenon, it is necessary to perform a certain process on the adjacent or adjoining boundary pixel units. In an embodiment, each boundary pixel unit is equally divided into a plurality of pixel division units having a same area, when it is determined that the area of the pixel division unit outside the display area occupies 50% or more of the area of the entire pixel division unit, a shading process is performed on the pixel division unit, that is, the entire pixel division unit is covered with a black opaque material, and thus the pixel division unit no longer displays. The more the pixel division units formed by dividing the boundary pixel unit, the smaller the display height difference between two adjacent or adjoining boundary pixel units, thereby reducing the sawtooth effect at the display boundary.

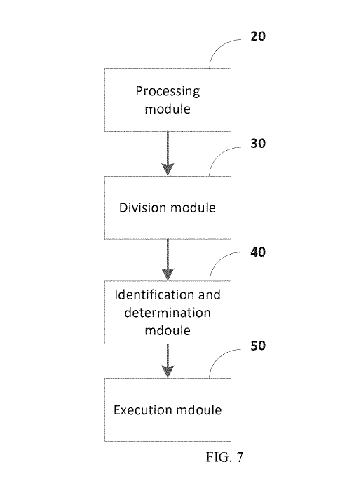

Referring to FIG. 7, embodiments of the present disclosure further provide a device for manufacturing an irregular shaped display panel, which may include modules in one-to-one correspondence with the steps in the above manufacturing method. In an embodiment, the device for manufacturing an irregular shaped display panel may include a processing module 20, a division module 30, an identification and determination module 40, and an execution module 50.

The processing module 20 is configured to determine, based on an irregular shaped region on the display panel, boundary pixel units on a boundary of the irregular shaped region.

The processing module 20 identifies and determines the boundary pixel units. Because the irregular shaped region may be arc-shaped, circle-shaped or slope-shaped, and is generally located at a boundary position of the entire display panel, in order to make display at the boundary of the entire display panel smoother, it is necessary to first distinguish the boundary pixel units in the irregular shaped region from other pixel units that perform display normally for the subsequent operation. A method for determining the boundary pixel units may include acquiring position information by scanning using software so as to identify the boundary pixel units. However, the present disclosure is not limited to this method, and may also adopt other method, as long as the boundary pixel units on the boundary of the irregular shaped region can be determined.

The division module 30 is configured to divide each boundary pixel unit into at least two pixel division units, and each of the pixel division units includes parts of all sub-pixels included in the boundary pixel unit.

In an embodiment, the division module 30 divides the boundary pixel unit along a cross-section of the boundary pixel unit. The division module 30 may determine the cross-section of the boundary pixel unit in various ways. For example, the cross-section may be determined by inputting parameters of the display penal itself and obtaining arrangement of the R sub-pixel, the G sub-pixel, and the B sub-pixel in the pixel unit of the display panel. Alternatively, relevant parameter information of the display panel may be automatically obtained through system scanning to determine the cross-section. Also, the cross-section may be determined by other known methods, which is not limited in the present disclosure.

The more the pixel division units formed by dividing a single boundary pixel unit, the smoother the display at the boundary position of the display panel. As described above, the boundary pixel unit may be equally divided, and the pixel division units formed by the division have a same area. For example, as shown in FIG. 3, each boundary pixel unit on the boundary of the irregular shaped region of the display panel is equally divided into two pixel division units, or as shown in FIG. 4, each boundary pixel unit on the boundary of the irregular shaped region of the display panel is equally divided into four pixel division units.

In addition, the dividing process performed by the division module 30 is not an actual and physical division, but a virtual division controlled through software. Each boundary pixel unit is divided into a plurality of pixel division units, and each pixel division unit can perform display separately (i.e., the plurality of pixel division units included in a single boundary pixel unit may have different display states).

The identification and determination module 40 is configured to determine a pixel division unit to be shaded. For example, whether a pixel division unit needs to undergo a shading processing is determined by determining whether a ratio of an area outside the display area to the total area in the pixel division unit reaches a preset value. If the ratio of the area outside the display area to the total area in the pixel division unit reaches the preset value, the pixel division unit is a pixel division unit to be shaded.

The identification and determination module 40 may be configured to identify the positions and the number of the pixel division units of each boundary pixel unit, determine whether the position of each pixel division unit is completely located in the display area, partially located in the display area, or not located in the display area at all, and determine, only for every pixel division unit that is partially located in the display area, whether the ratio of the area of the pixel division unit outside the display area to an area of the entire pixel division unit reaches a preset value, thereby identifying the pixel division unit to be shaded.

The preset value herein may be any value, but during identification and determination, the preset value is a fixed value in the device. The preset value may be set in advance as required, and may be 50%.

The identification and determination module 40 may determine whether a pixel division unit needs to undergo the shading processing in various ways, for example, by determining whether a ratio of the area of the pixel division unit outside the display area to the total area of the pixel division unit reaches a preset value, or by determining whether a ratio of an area of the pixel division unit inside the display area to the total area of the pixel division unit reaches a preset value. The foregoing two methods result in a same display effect when the preset value is 50%, but when the preset value is not 50%, the display effects will be different. The determining method may be provided in advance in the device.

The execution module 50 is configured to perform a shading process on the pixel division unit to be shaded determined by the identification and determination module 40 (that is, a shading process is performed on the pixel division unit whose ratio of the area outside the display area to the total area reaches the preset value).

After the identification and determination module 40 identifies and determines all of the pixel division units to be shaded, a corresponding mask is designed according to the positions of the pixel division units to be shaded, so that the shading units are respectively formed on the pixel division units whose ratios of the areas outside the display area to the total area reach the preset value while forming the black matrix using the mask, so as to permanently and physically block light emission of the pixel division units. In other words, the black matrix of the display panel in the present disclosure includes not only a conventional black matrix structure but also the shading units formed on the pixel division units whose ratios of the areas outside the display area to the total area reach the preset value (i.e., the shading units are formed as a part of the black matrix). In an embodiment, the execution module 50 in the present disclosure is a device for forming a black matrix in the related art, which is not described in detail herein.

In the present disclosure, the processing module 20 is coupled to the division module 30, the division module 30 is coupled to the identification and determination module 40, and the identification and determination module 40 is coupled to the execution module 50. The division module 30 divides the boundary pixel unit into at least two pixel division units, and each pixel division unit includes parts of the R sub-pixel, G sub-pixel and B sub-pixel that can implement full color display. In the present disclosure, the division module does not physically divide the boundary pixel unit, but control segmentations of the R sub-pixel, G sub-pixel and B sub-pixel to be displayed through a software algorithm, and from display state, display of the respective segmentations of the R sub-pixel, G sub-pixel and B sub-pixel is just like that the entire boundary pixel unit is physically divided into a plurality of independent pixel division units.

It should be noted that the processing module 20, the division module 30, and the identification and determination module 40 according to an embodiment of the present disclosure may be implemented as a memory and a processor coupled to each other. The memory stores computer executable instructions, which are executable by the processor to cause the processor to achieve the functions of the processing module 20, the division module 30, and the identification and determination module 40. Examples of a suitable memory include, but are not limited to, magnetic disc or magnetic tape; optical storage media such as compact disc (CD) or DVD (digital versatile disc); flash memory; and other nonvolatile medium. Optionally, the memory is a nonvolatile memory. Of course, the device according to the embodiments of the present disclosure is not limited thereto, and may be implemented in other form in which software and hardware are combined.

In the present disclosure, the boundary pixel unit may be equally divided into two or four pixel division units, or 2*n pixel division units, for ease of implementation. In a case where the boundary pixel unit is divided into two pixel division units, the determined boundary pixel unit is equally divided into two pixel division units. In a case where the boundary pixel unit is divided into four pixel division units, the boundary pixel unit may be first divided into two pixel division units, each of which is then equally divided into two pixel division units. In a case where the boundary pixel unit is divided into eight pixel division units, each of the formed four pixel division units is further equally divided into two pixel division units, and so on.

In an embodiment, the identification and determination module 40 identifies an area of each pixel division unit in the display area and calculates a ratio of the area to an area of the entire pixel division unit, and then compares the ratio with a preset value. In an embodiment, the present value may be set to be 50%, which makes the display more uniform.

The identification and determination module 40 is configured to identify the positions and the number of the pixel division units of each boundary pixel unit; Optionally, the positions and the number of the pixel division units of the boundary pixel unit may be identified using various methods, for example, by obtaining parameters of the pixel division units through progressive scan, or by retrieving parameters directly set in the device.

The identification and determination module 40 is further configured to identify the position of each pixel division unit, that is, determine whether the pixel division unit is completely located in the display area, partially located in the display area, or not located in the display area at all (i.e., completely located in the non-display area). The positions of the pixel division units are determined for subsequent determination.

For each pixel division unit partially located in the display area, it is further determined whether a ratio of the area of the pixel division unit outside the display area to the total area of the pixel division unit is equal to or larger than a preset value. The pixel division unit(s) completely located in the display area or completely in the non-display area is automatically filtered and will not undergo the process of this step, and only when the pixel division unit is determined to be partially located in the display area, whether a ratio of the area of the pixel division unit outside the display area to the total area of the pixel division unit reaches a preset value is further determined.

However, the method for determining whether each pixel division unit needs to undergo the shading process here is not limited to determining whether a ratio of the area of the pixel division unit outside the display area to the total area of the pixel division unit reaches a preset value, and may include: determining whether a ratio of an area of the pixel division unit inside the display area to the total area of the pixel division unit reaches a preset value (e.g., 50%). The two methods result in a same display effect when the preset value is 50%, but when the preset value is not 50%, the display effects will be different. Needless to say, the determination in this step in the present disclosure may be achieved by other method, and the method is included in the protection scope of the present disclosure, as long as its purpose is to compare the ratio of the area of the pixel division unit in the display area to the total area of the pixel division unit with a preset value.

When the ratio of the area outside the display area to the total area in the pixel division unit reaches the preset value, an execution instruction indicating the shading process is sent to the execution module.

Optionally, in an embodiment, the preset value may be set to be 50%, and the step for determining whether each pixel division unit needs to undergo the shading process here is not limited to determining whether the ratio of the area of the pixel division unit outside the display area to the area of the entire pixel division unit reaches a preset value. It is also possible to determine whether a ratio of the area of the pixel division unit inside the display area to the area of the entire pixel division unit reaches a preset value, and an execution instruction indicating the shading process is sent to the execution module when the preset value is not reached. The foregoing two methods can be used, and they differ only in the reference object of the preset value, and have the same working principle.

In an embodiment, the position of the pixel division unit may be identified to be completely in the display area. When the pixel division unit is completed located in the display area, the pixel division unit is no longer subjected to further determination. Similarly, when the pixel division unit is not located in the display area at all (i.e., completely located in the non-display area), the pixel division unit is no longer subjected to further determination.

In an embodiment, a method used by the execution module 50 to perform the shading process includes: using a black opaque material (e.g., a material forming a black matrix) to block light transmissive areas of R sub-pixel, G sub-pixel and B sub-pixel in the pixel division unit that needs to be shaded, so that the pixel division unit is permanently and physically blocked, thereby achieving irregular shaped display.

In another embodiment, the present disclosure also provides an irregular shaped display panel, which is manufactured using the above-described manufacturing method. The specific manufacturing method may include steps S100, S200, S300 and S400 as described above, and the specific implementation process will not be repeatedly described here.

Since each pixel division unit has parts of R sub-pixel, G sub-pixel and B sub-pixel, each pixel division unit can perform normal display. In an embodiment, each boundary pixel unit is equally divided into two or four pixel division units.

In an embodiment, the preset value is set to be 50%, and a shading unit is provided on the pixel division unit when a ratio of an area of the pixel division unit outside the display area to an area of the entire pixel division unit is larger than or equal to 50%. The shading unit is made of a black opaque material.

The irregular shaped display panel in the embodiment may be manufactured by using the above-described manufacturing device including the processing module 20, the division module 30, the identification and determination module 40, and the execution module 50. The processing module 20 is mainly configured to determine, based on an irregular shaped region on the display panel, boundary pixel units on a boundary of the irregular shaped region. The division module 30 is mainly configured to equally divide each boundary pixel unit into at least two pixel division units. The identification and determination module 40 is mainly configured to determine whether a ratio of an area of each pixel division unit outside the display area to an area of the entire pixel division unit reaches a preset value. The execution module 50 is mainly configured to perform a shading process on the pixel division unit when the identification and determination module determines that the ratio of the area of the pixel division unit outside the display area to the area of the entire pixel division unit reaches the preset value.

The connection and working principle of respective modules may refer to the above description and are not repeatedly described herein.

Embodiments of the present disclosure further provide a display device, which comprises any one of the irregular shaped display panels described above. The device described herein may include a product that needs to perform display, such as a watch, a smart phone, a computer, a television, etc., and the irregular shaped display panel in the present disclosure is particularly suitable for the display device having a circular shape or other irregular shape.

The present disclosure provides an irregular shaped display panel, a manufacturing method and a manufacturing device of an irregular shaped display panel, and a display device. In the manufacturing method, by determining the boundary pixel units on the boundary of the irregular shaped region, dividing each boundary pixel unit into at least two pixel division units, determining the relationship between the ratio of the area of each pixel division unit outside the display area to the total area of the pixel division unit and a preset value, and performing a shading processing on the pixel division unit based on the determination, each pixel division unit not subjected to the shading processing can perform display independently. Since each boundary pixel unit is divided into a plurality of pixel division units, the sawtooth effect in the irregular shaped display area is alleviated during display. This is equivalent to refining the irregular shaped display area, so as to avoid obvious serrations and burrs during display of many existing irregular shaped display products on the market, making the step between rows of boundary pixel units small. As a result, the contour display is smoother and more delicate, the user experience and competitiveness of the product are improved, and the problem of defective color bar at the edge due to a design simply according to the irregular shape is avoided.

The irregular shaped display panel, the method and device for manufacturing an irregular shaped display panel, and the display device provided by the present application are described in detail above. The principle and implementations of the present application are set forth herein by way of specific examples, and the foregoing description of the embodiments is only used to facilitate understanding the method and core ideas of the present application. In the meanwhile, persons of ordinary skill in the art may make modifications to the present application in terms of the specific implementations and application scopes based on the ideas of the present application. Therefore, the specification shall not be constructed as limitations to the present application.

1. A method for manufacturing an irregular shaped display panel, the irregular shaped display panel comprising a display area and a non-display area surrounding the display area, the method comprising:
determining, based on an irregular shaped region on the display panel, boundary pixel units located on a boundary of the irregular shaped region;
dividing each boundary pixel unit into at least two pixel division units such that each of the at least two pixel division units comprises parts of all sub-pixels of the boundary pixel unit; and
determining whether a ratio of an area of each pixel division unit outside the display area to an area of the entire pixel division unit is greater than or equal to a preset value; if it is determined that the ratio is greater than or equal to the preset value, performing a shading process on the pixel division unit.

2. The method for manufacturing an irregular shaped display panel of claim 1, wherein each boundary pixel unit comprises a red sub-pixel, a green sub-pixel, and a blue sub-pixel, and each pixel division unit of the boundary pixel unit comprises parts of the red sub-pixel, the green sub-pixel, and the blue sub-pixel.

3. The method for manufacturing an irregular shaped display panel of claim 1, wherein when the ratio of the area of each pixel division unit outside the display area to the area of the entire pixel division unit is greater than or equal to 50%, the shading process is performed on the pixel division unit.

4. The method for manufacturing an irregular shaped display panel of claim 1, wherein the step of performing a shading process on the pixel division unit comprises:
covering the pixel division unit with a black opaque material.

5. The method for manufacturing an irregular shaped display panel of claim 1, wherein each boundary pixel unit is equally divided into two pixel division units or four pixel division units.

6. The method for manufacturing an irregular shaped display panel of claim 1, wherein the step of determining whether a ratio of an area of each pixel division unit outside the display area to an area of the entire pixel division unit is greater than or equal to a preset value comprises: identifying positions and the number of the at least two pixel division units of each boundary pixel unit; determining whether each pixel division unit is completely located in the display area, partially located in the display area, or not located in the display area at all, and determining, only for every pixel division unit that is partially located in the display area, whether the ratio of the area of the pixel division unit outside the display area to the area of the entire pixel division unit is greater than or equal to the preset value.

7. The method for manufacturing an irregular shaped display panel of claim 5, wherein each boundary pixel unit is equally divided into two pixel division units or four pixel division units having a same area.

8. A device for manufacturing an irregular shaped display panel, the irregular shaped display panel comprising a display area and a non-display area surrounding the display area, and the device comprising:
a processing module, configured to determine, based on an irregular shaped region on the display panel, boundary pixel units on a boundary of the irregular shaped region;
a division module, configured to divide each boundary pixel unit into at least two pixel division units such that each pixel division unit comprises parts of all sub-pixels of the boundary pixel unit;
an identification and determination module, configured to determine whether a ratio of an area of each pixel division unit outside the display area to an area of the entire pixel division unit is greater than or equal to a preset value; and
an execution module, configured to perform a shading process on the pixel division unit when the identification and determination module determines that the ratio of the area of the pixel division unit outside the display area to the area of the entire pixel division unit is greater than or equal to the preset value.

9. The device for manufacturing an irregular shaped display panel of claim 8, wherein each boundary pixel unit comprises a red sub-pixel, a green sub-pixel, and a blue sub-pixel, and each pixel division unit of the boundary pixel unit comprises parts of the red sub-pixel, the green sub-pixel, and the blue sub-pixel.

10. The device for manufacturing an irregular shaped display panel of claim 8, wherein the execution module performs the shading process on the pixel division unit when the identification and determination module determines that the ratio of the area of the pixel division unit outside the display area to the area of the entire pixel division unit is equal to or greater than 50%.

11. The device for manufacturing an irregular shaped display panel of claim 8, wherein a material used by the execution module to perform the shading process on the pixel division unit is a black opaque material.

12. The device for manufacturing an irregular shaped display panel of claim 8, wherein the division module is configured to equally divide each boundary pixel unit into two pixel division units or four pixel division units.

13. The device for manufacturing an irregular shaped display panel of claim 8, wherein the identification and determination module is configured to identify positions and the number of the at least two pixel division units of each boundary pixel unit; determine whether each pixel division unit is completely located in the display area, partially located in the display area, or not located in the display area at all, and determine, only for every pixel division unit that is partially located in the display area, whether the ratio of the area of the pixel division unit outside the display area to the area of the entire pixel division unit is greater than or equal to the preset value.

14. The device for manufacturing an irregular shaped display panel of claim 12, wherein the division module is configured to equally divide each boundary pixel unit into two pixel division units or four pixel division units having a same area.

15. An irregular shaped display panel, comprising a display area and a non-display area surrounding the display area, wherein each boundary pixel unit on a boundary of an irregular shaped region is divided into at least two pixel division units, and in each boundary pixel unit, the pixel division unit is covered by a shading unit when a ratio of an area of the pixel division unit outside the display area to an area of the entire pixel division unit is greater than or equal to a preset value.

16. The irregular shaped display panel of claim 15, wherein in each boundary pixel unit, the pixel division unit is covered by the shading unit when a ratio of the area of the pixel division unit outside the display area to the area of the entire pixel division unit is greater than or equal to 50%.

17. The irregular shaped display panel of claim 15, wherein the shading unit is made of a black opaque material.

18. The irregular shaped display panel of claim 15, wherein each boundary pixel unit comprises a red sub-pixel, a green sub-pixel, and a blue sub-pixel, and each pixel division unit of the boundary pixel unit comprises parts of the red sub-pixel, the green sub-pixel, and the blue sub-pixel.

19. The irregular shaped display panel of claim 15, wherein each boundary pixel unit is equally divided into two pixel division units or four pixel division units having a same area.

20. A display device, comprising the irregular shaped display panel of claim 15.
